(19) United States
(12) Patent Application Publication
(10) Pub. No.: US 2002/0142601 A1
(43) Pub. Date: Oct. 3, 2002

(54) Method for planarizing a surface of a semiconductor wafer with a fixed abrasive material

(76) Inventors: John M. Boyd, Atascadero, CA (US); David Wei, Fremont, CA (US); Katrina A. Mikhaylichenko, San Jose, CA (US)

Correspondence Address: MARTINE & PENILLA, LLP, 710 LAKEWAY DRIVE, SUITE 170, SUNNYVALE, CA, 94085, US

(21) Appl. No.: 09/823,468

(22) Filed: Mar. 30, 2001

(51) Int. Cl. H01L 21/302

(52) U.S. Cl. 438/690

(57) ABSTRACT

In a method for planarizing a surface of a semiconductor wafer, a fixed abrasive material having micro-replicated features is provided. A wafer carrier holding a semiconductor wafer is disposed over the fixed abrasive material. The wafer carrier is configured to prevent significant activation of the micro-replicated features by a leading edge of the semiconductor wafer. A surface of the semiconductor wafer is contacted with the fixed abrasive material as the fixed abrasive material moves relative to the wafer carrier. Material removal occurs while features on the surface of the semiconductor wafer activate the micro-replicated features of the fixed abrasive material. Material removal substantially stops when there are no features remaining on the surface of the semiconductor wafer. A method for controlling activation of a fixed abrasive material by a leading edge of a semiconductor wafer during planarization of a surface of the semiconductor wafer also is described.

### BACKGROUND OF THE INVENTION

The present invention relates generally to semiconductor fabrication and, more particularly, to a method for planarizing a surface of a semiconductor wafer with a fixed abrasive material.

Chemical mechanical planarization (CMP) is a well-known technique for planarizing the surface of a semiconductor wafer. In known CMP processes, the abrasive material may be either loose, e.g., dispersed in a slurry, or fixed, e.g., dispersed in a solid matrix. The mechanisms of loose abrasive CMP processes are fairly well known to those skilled in the art; however, the mechanisms related to fixed abrasive CMP processes are less understood.

FIG. 1A is a simplified schematic diagram that illustrates a conventional fixed abrasive CMP process for planarizing a dielectric layer on a semiconductor substrate. As shown in FIG. 1A, semiconductor substrate 102 includes active regions and shallow trench isolation regions 103, which are filled by dielectric layer 104 so that the active regions are electrically isolated from one another. Dielectric layer 104 includes topographic features 104a that are to be removed in the process of planarizing the surface of the dielectric layer. Fixed abrasive layer 108, which is in a belt format, is disposed on backing 106. Fixed abrasive layer 108 includes abrasive particles 112, e.g., CeO₂ particles, dispersed in a polymer matrix and has micro-replicated features 110 formed on an upper surface thereof.

As shown in FIG. 1A, fixed abrasive layer 108 moves in the direction of the arrow. The abrasion of the polymer matrix by topographic features 104a is believed to activate CeO₂ particles by physically exposing fresh particles and by removing the hydroxylated boundary layer from exposed CeO₂ particles that have been in contact with a previous substrate. Material removal occurs when activated CeO₂ particles remove dielectric material from dielectric layer 104 through the well-known hydroxylation/polysilicate formation process. In principle, this material removal process should stop automatically once all the topographic features 104a have been planarized because there are no features remaining to activate the CeO₂ particles in micro-replicated features 110. Thus, the material removal rate should slow by one or more orders of magnitude. In practice, however, continued material removal has been observed after planarization has been achieved.

It is believed that the configuration of current wafer carriers is the primary cause for the post-planarization material removal observed in conventional fixed abrasive CMP processes. FIG. 1B shows a conventional wafer carrier applying a surface of a semiconductor wafer to a fixed abrasive material in a belt format. As shown in FIG. 1B, wafer support assembly 130 includes wafer carrier 132, and retaining ring 134 affixes wafer 136 to the wafer carrier. Gimbal 138 includes a ball and socket assembly having a radius of curvature, r, such that carrier gimbal point 140 is well above the surface of the wafer that is being planarized. When wafer 136 is brought into contact with fixed abrasive layer 108, which is moving in the direction of the arrow shown in FIG. 1B, the force applied on the surface of wafer 136 defines moment arm 137 and results in moment 142 being applied on wafer carrier 132. Consequently, leading edge 136a of wafer 136 tilts in the direction of the incoming fixed abrasive layer 108, as indicated by arrow 144. This contact between leading edge 136a and fixed abrasive layer 108 increases the degree to which the leading edge activates CeO₂ particles in the micro-replicated features of the fixed abrasive layer to the point that material removal still occurs after full planarization has been achieved.

The activation of CeO₂ particles by leading edge 136a is problematic because it eliminates the self-stopping characteristic of the fixed abrasive CMP process. This is undesirable because excess material may be removed from the substrate, as illustrated in FIG. 1C. As shown therein, the level of the upper surface of semiconductor substrate 102 is below the desired level 102a and the level of the upper surface of shallow trench isolation regions 104 is below the desired level 104a.

In view of the foregoing, there is a need for a method for preventing the leading edge of a substrate from activating the micro-replicated features of a fixed abrasive material so that material removal stops when planarization is achieved.

### SUMMARY OF THE INVENTION

Broadly speaking, the present invention fills this need by providing a wafer carrier configuration that prevents significant activation of micro-replicated features of a fixed abrasive material by the leading edge of a semiconductor wafer.

In accordance with one aspect of the invention, a method for planarizing a surface of a semiconductor wafer is provided. In this method, a fixed abrasive material having micro-replicated features is provided. A wafer carrier holding a semiconductor wafer is disposed over the fixed abrasive material. The wafer carrier is configured to prevent significant activation of the micro-replicated features by a leading edge of the semiconductor wafer. A surface of the semiconductor wafer is contacted with the fixed abrasive material as the fixed abrasive material moves relative to the wafer carrier. Material removal occurs while features on the surface of the semiconductor wafer activate the micro-replicated features of the fixed abrasive material. Material removal substantially stops when there are no features remaining on the surface of the semiconductor wafer.

In one embodiment, the wafer carrier is a projected gimbal wafer carrier having a gimbal point at approximately the surface of the semiconductor wafer. In one embodiment, this gimbal point is below the surface of the semiconductor wafer. In another embodiment, the wafer carrier has a fluid membrane. In one embodiment, the fixed abrasive material is in a belt format. In one embodiment, the fixed abrasive material includes CeO₂ particles dispersed in a polymer matrix.

In accordance with another aspect of the invention, a method for controlling activation of a fixed abrasive material by a leading edge of a semiconductor wafer during planarization of a surface of the semiconductor wafer is provided. In this method, the orientation of a wafer carrier is controlled such that a leading edge of a semiconductor wafer held by the wafer carrier either remains substantially parallel to or moves away from a surface of an incoming fixed abrasive material.

In one embodiment, the fixed abrasive material has micro-replicated features, and the orientation of the wafer carrier is controlled to prevent the micro-replicated features from being significantly activated by the leading edge of the semiconductor wafer. In one embodiment, the wafer carrier is a projected gimbal wafer carrier. In another embodiment, the wafer carrier has a fluid membrane.

The methods of the present invention advantageously improve the self-stopping characteristic of a fixed abrasive CMP process. The methods also reduce dishing in an STI process.

It is to be understood that the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1A is a simplified schematic diagram that illustrates a conventional fixed abrasive CMP process for planarizing a dielectric layer on a semiconductor substrate.

FIG. 1B shows a conventional wafer carrier applying a surface of a semiconductor wafer to a fixed abrasive material in a belt format.

FIG. 1C is a cross-sectional view of a wafer section that has been planarized in accordance with conventional techniques using a fixed abrasive material.

FIG. 2 is a simplified schematic diagram of an exemplary chemical mechanical planarization (CMP) system in accordance with one embodiment of the present invention.

FIG. 3 is a simplified schematic diagram of a wafer support assembly including a projected gimbal wafer carrier in accordance with one embodiment of the present invention.

FIG. 4 is a cross-sectional view of a wafer section that has been planarized in accordance with the invention using a fixed abrasive material.

FIG. 5 is a simplified schematic diagram of an exemplary alternative wafer carrier that includes a fluid membrane.

FIG. 6 is a flowchart diagram illustrating the method operations performed in planarizing the surface of a semiconductor wafer in accordance with one embodiment of the present invention.

### DETAILED DESCRIPTION OF EXEMPLARY EMBODIMENTS

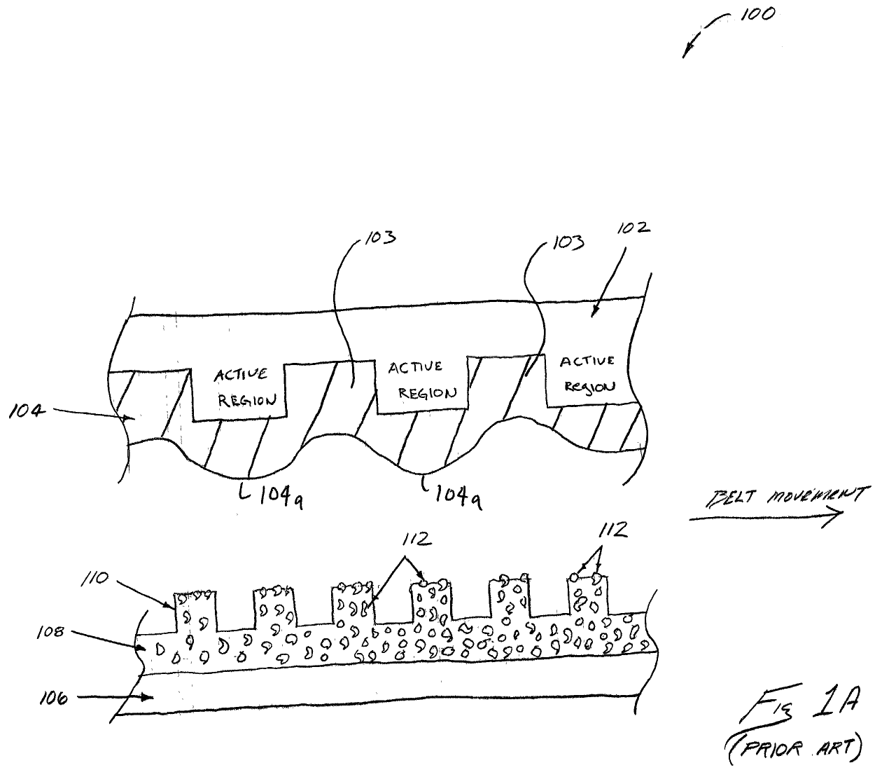

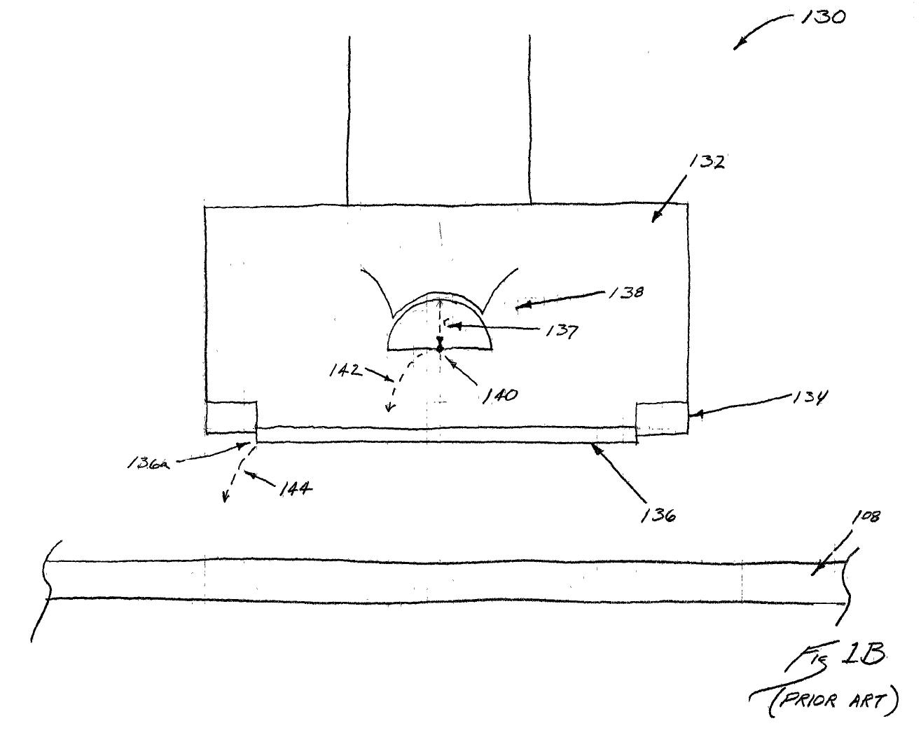

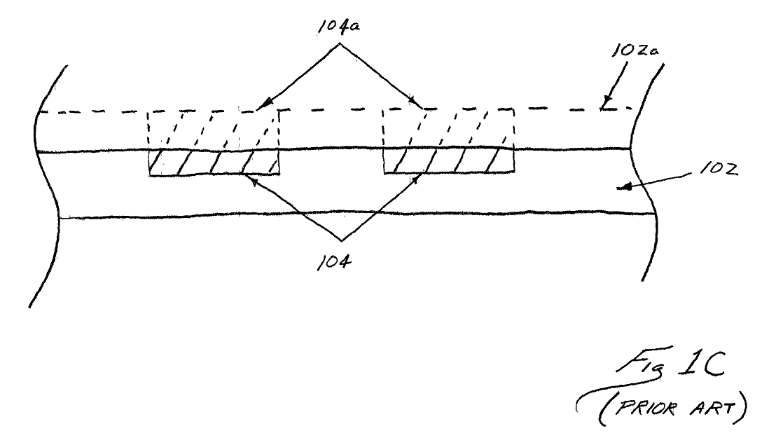

Several exemplary embodiments of the invention will now be described in detail with reference to the accompanying drawings. FIGS. 1A-1C are described above in the “Background of the Invention” section.

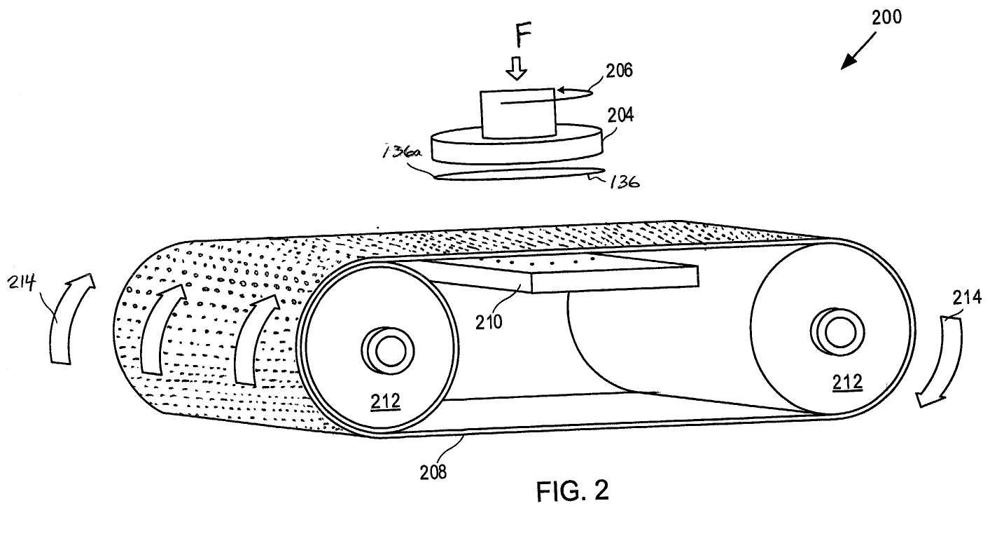

FIG. 2 is a simplified schematic diagram of an exemplary chemical mechanical planarization (CMP) system in accordance with one embodiment of the present invention. As shown in FIG. 2, CMP system 200 is a fixed abrasive CMP system, so designated because the preparation surface is an endless fixed abrasive material belt 208. Fixed abrasive material belt 208 is mounted on two drums 212, which drive the belt in a rotational motion in the direction indicated by arrows 214.

Wafer 136 is mounted on wafer carrier 204, which is rotated in direction 206. To carry out a planarization process, rotating wafer 136 is applied against the rotating fixed abrasive material belt 208 with a force F. As is well known to those skilled in the art, the force F may be varied to meet the demands of particular planarization processes. Platen 210, which is disposed below fixed abrasive material belt 208, stabilizes the belt and provides a solid surface onto which wafer 136 may be applied. As described above, the topographic features of wafer 136 activate the micro-replicated features of fixed abrasive material belt 208. Wafer carrier 204 is configured to prevent significant activation of the micro-replicated features of fixed abrasive material belt 208 by leading edge 136a of wafer 136, as will explained in more detail below. Thus, when the topographic features of wafer 136 are planarized, there are no remaining topographic features to activate the micro-replicated features of fixed abrasive material belt 208. As a result, the material removal rate slows by one or more orders of magnitude, thereby providing the CMP process with an automatic stopping characteristic referred to herein as “self-stopping.”

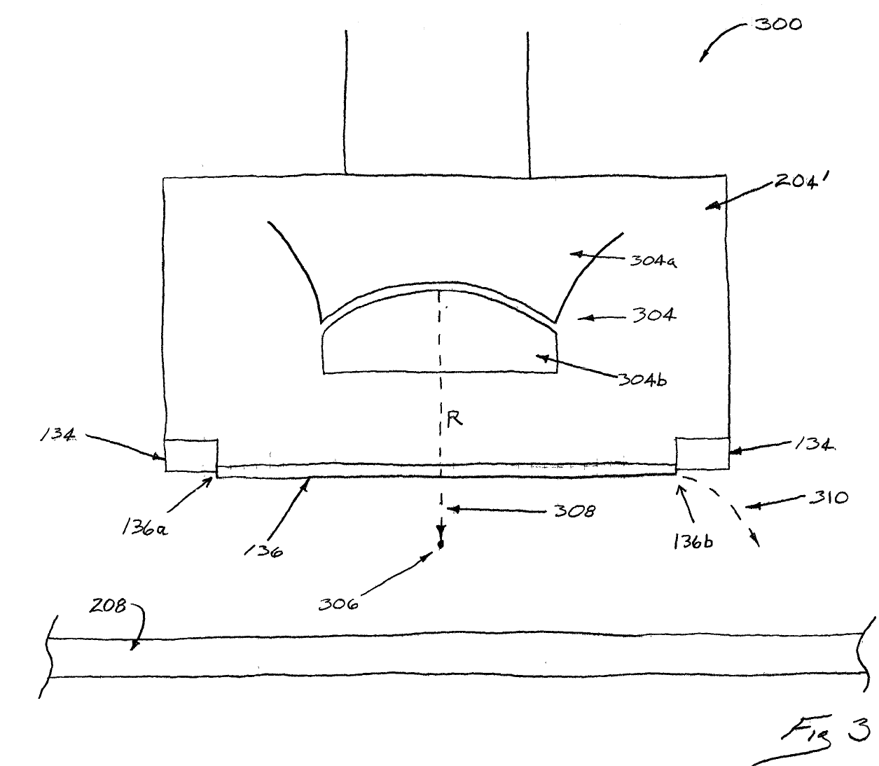

FIG. 3 is a simplified schematic diagram of a wafer support assembly including a projected gimbal wafer carrier in accordance with one embodiment of the present invention. As shown in FIG. 3, wafer support assembly 300 includes projected gimbal wafer carrier 204′, and retaining ring 134 affixes wafer 136 to the projected gimbal wafer carrier. Projected gimbal structure 304, which includes socket 304a and ball 304b, allows wafer carrier 204′ to pivot so that the surface of wafer 136 can naturally conform to the surface of fixed abrasive material belt 208 during planarization. Projected gimbal structure 304 is configured so that the gimbal point 306, which is defined by the radius of curvature, R, occurs approximately at or below the surface of wafer 136 (as shown in FIG. 3, gimbal point 306 occurs below the surface of wafer 136). This prevents significant activation of the micro-replicated features of fixed abrasive material belt 208 by leading edge 136a of wafer 136, as explained in more detail below.

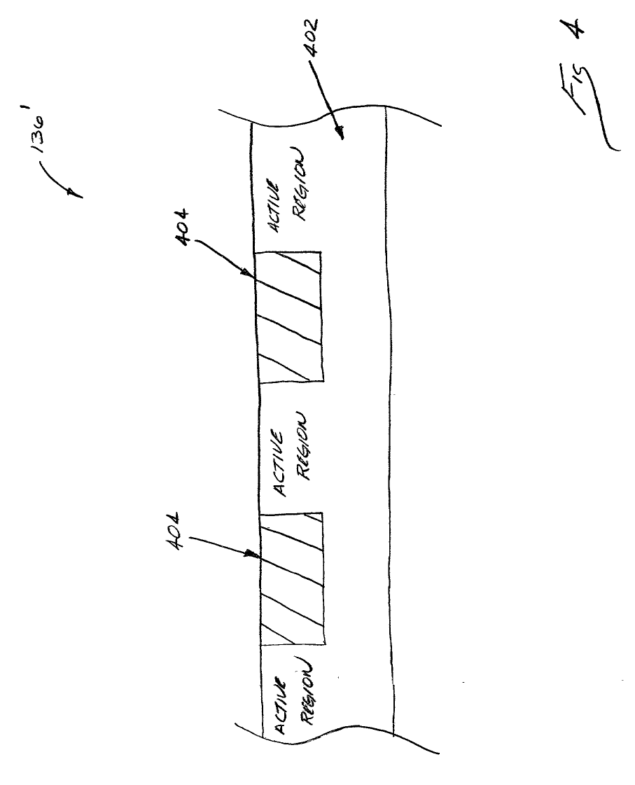

When wafer 136 is applied to fixed abrasive material belt 208, the location of gimbal point 306 causes the force applied on the surface of the wafer to define a moment arm that results in moment 308 being applied on wafer carrier 204′. Consequently, trailing edge 136b of wafer 136 tilts in the direction of incoming fixed abrasive material belt 208, as indicated by arrow 310. In turn, leading edge 136a of wafer 136 tilts away from, i.e., in the opposite direction of, incoming fixed abrasive material belt 208. The degree to which leading edge 136a moves away from fixed abrasive material belt 208 may be controlled so that the leading edge does not cause any significant activation of the micro-replicated features of the fixed abrasive material belt. By significantly reducing or eliminating the activation of micro-replicated features by the leading edge of the wafer, the self-stopping characteristic of the fixed abrasive CMP process is significantly improved. In addition, dishing effects are minimized, as described below with reference to FIG. 4.

FIG. 4 is a cross-sectional view of wafer section 136′ that has been planarized in accordance with the invention using a fixed abrasive material. As shown in FIG. 4, wafer section 136′ includes substrate 402 having active regions separated by shallow trench isolation (STI) regions 404, which are filled with a dielectric material, e.g., oxide. As shown, the oxide of STI regions 404 has been planarized so that the upper surfaces of the STI regions are even with the upper surface of substrate 402 at a desired level. In addition, the dishing in STI regions 404, which is problematic in conventional fixed abrasive CMP processes, is reduced. These advantageous results are achieved by controlling the activation of the micro-replicated features of the fixed abrasive material belt by the leading edge of the wafer in accordance with the present invention.

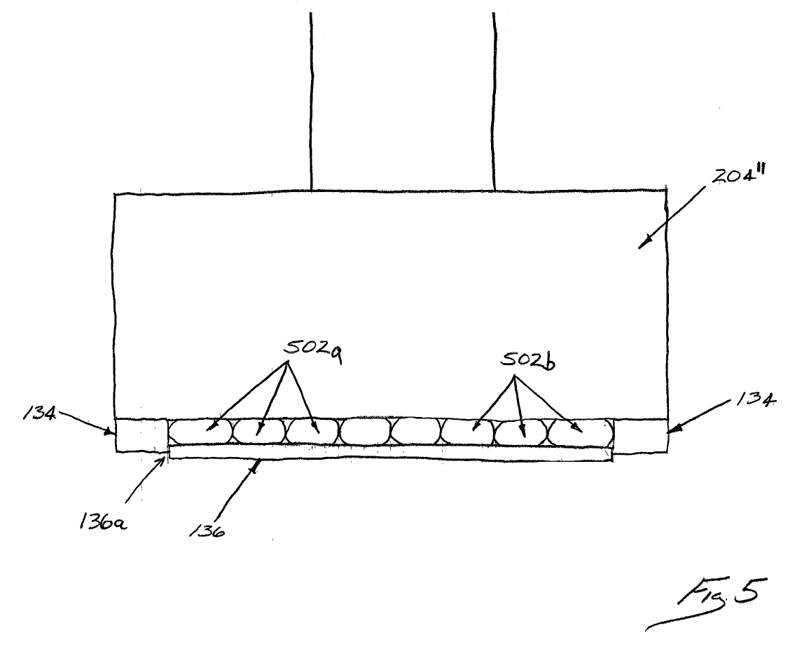

It will be apparent to those skilled in the art that the use of a projected gimbal wafer carrier is not the only way to prevent the leading edge of the wafer from causing significant activation of the micro-replicated features of the fixed abrasive material. FIG. 5 is a simplified schematic diagram of an exemplary alternative wafer carrier that includes a fluid membrane. As shown in FIG. 5, wafer carrier 204″ includes a fluid membrane having a plurality of bladder regions 502a and 502b, and retaining ring 134 affixes wafer 136 to the wafer carrier. As is well known to those skilled in the art, fluid, e.g., air, may be injected into bladder regions 502 of the fluid membrane to apply pressure on wafer 136. During planarization, the fluid membrane allows the surface of wafer 136 to conform naturally to the surface of fixed abrasive material belt.

The gimbal point of a wafer carrier including a fluid membrane is typically very close to the surface of wafer 136. Accordingly, it may not be necessary to adjust the pressure the fluid membrane applies on wafer 136 to avoid having leading edge 136a cause significant activation of the micro-replicated features of the fixed abrasive material belt. If significant activation occurs, however, then the pressure the fluid membrane applies on wafer 136 may be controlled so that bladder regions 502b apply more pressure on the wafer than bladder regions 502a, with the result that leading edge 136a tilts away from the incoming fixed abrasive material belt. By way of example, this may be accomplished by directing more fluid to bladder regions 502b than is directed to bladder regions 502a. Those skilled in the art will recognize that wafer carriers having fluid membranes without bladder regions also may be used to implement the principles of the invention.

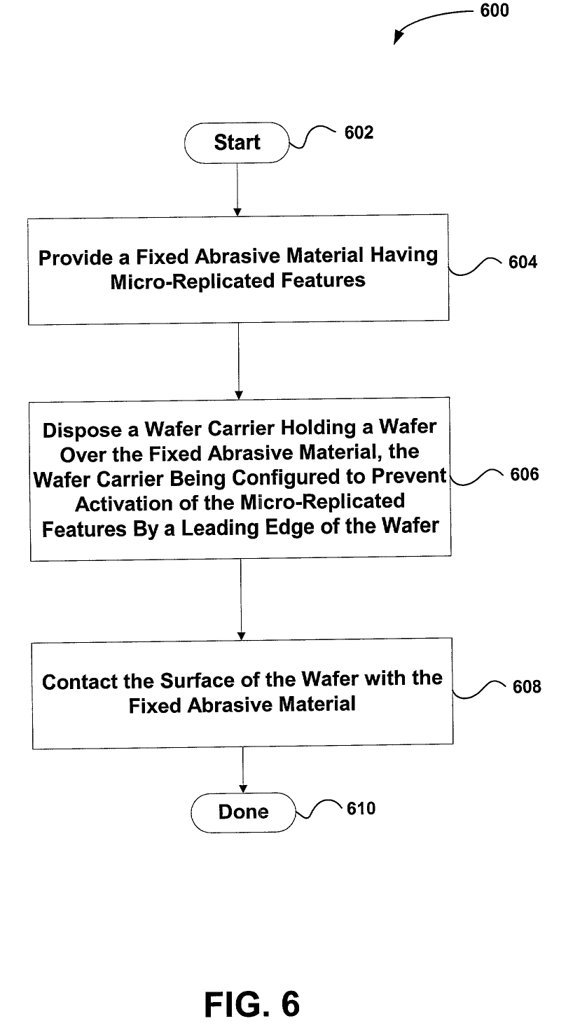

FIG. 6 is a flowchart diagram 600 illustrating the method operations performed in planarizing the surface of a semiconductor wafer in accordance with one embodiment of the present invention. In an initial operation 602, any required preprocess operations may be performed. By way of example, the preprocess operations may include etching STI structures into the substrate of a wafer, affixing the wafer in the wafer carrier, and other preprocess operations that will be apparent to those skilled in the art. In operation 604, a fixed abrasive material having micro-replicated features is provided. In one embodiment, the fixed abrasive material is in a belt format. In one embodiment, the fixed abrasive material includes abrasive CeO₂ particles dispersed in a polymer matrix. Suitable fixed abrasive materials having micro-replicated features are commercially available from 3M Corporation.

In operation 606, a wafer carrier holding a wafer is disposed over the fixed abrasive material. The wafer carrier is configured to prevent significant activation of the micro-replicated features of the fixed abrasive material by the leading edge of the wafer. In one embodiment, the wafer carrier may be a projected gimbal wafer carrier that includes a projected gimbal structure that includes a ball and socket having a radius of curvature configured to project the gimbal point at approximately the surface of the wafer or below the surface of the wafer. In another embodiment, the wafer carrier may include a fluid membrane. The configurations of these wafer carriers ensure that the leading edge of the wafer either remains substantially parallel, i.e., neutral, to the surface of the incoming fixed abrasive material or tilts away from the surface of the incoming fixed abrasive material.

In operation 608, the surface of the wafer is contacted with the fixed abrasive material as the fixed abrasive material moves relative to the wafer carrier. Because of the configuration of the wafer carrier, material removal occurs while topographic features on the surface of the wafer activate the micro-replicated features of the fixed abrasive material. Material removal substantially stops when there are no topographic features remaining on the surface of the wafer, i.e., the surface is planarized. In other words, the material removal process is self-stopping. As used herein, the phrase “material removal substantially stops” means that the rate of material removal slows by at least an order of magnitude. Any necessary post-process operations are performed in operation 610. Post-process operations may include dismounting the wafer from the wafer carrier, additional etching of the wafer, and other post-process operations that will be apparent to those skilled in the art.

The methods of the present invention advantageously improve the self-stopping characteristic of a fixed abrasive CMP process. The methods also reduce dishing in an STI process. It is believed that these advantages also may be significant in alternative fixed abrasive CMP processes, e.g., BPSG (ILD) fixed abrasive CMP.

In summary, the present invention provides a method for planarizing a surface of a semiconductor wafer. The invention has been described herein in terms of several exemplary embodiments. Other embodiments of the invention will be apparent to those skilled in the art from consideration of the specification and practice of the invention. The embodiments and preferred features described above should be considered exemplary, with the scope of the invention being defined by the appended claims and their equivalents.

What is claimed is:

1. A method for planarizing a surface of a semiconductor wafer, comprising:
providing a fixed abrasive material having micro-replicated features;
disposing a wafer carrier holding a semiconductor wafer over the fixed abrasive material, the wafer carrier being configured to prevent significant activation of the micro-replicated features by a leading edge of the semiconductor wafer; and
contacting a surface of the semiconductor wafer with the fixed abrasive material as the fixed abrasive material moves relative to the wafer carrier, wherein material removal occurs while features on the surface of the semiconductor wafer activate the micro-replicated features of the fixed abrasive material and material removal substantially stops when there are no features remaining on the surface of the semiconductor wafer.

2. The method of claim 1, wherein the wafer carrier is a projected gimbal wafer carrier having a gimbal point at approximately the surface of the semiconductor wafer.

3. The method of claim 1, wherein the wafer carrier is a projected gimbal wafer carrier having a gimbal point below the surface of the semiconductor wafer.

4. The method of claim 1, wherein the wafer carrier has a fluid membrane.

5. The method of claim 1, wherein the fixed abrasive material is in a belt format.

6. The method of claim 1, wherein the fixed abrasive material comprises CeO₂ particles dispersed in a polymer matrix.

7. A method for planarizing a surface of a semiconductor wafer, comprising:
providing a fixed abrasive material having micro-replicated features;
disposing a projected gimbal wafer carrier holding a semiconductor wafer over the fixed abrasive material; and
contacting a surface of the semiconductor wafer with the fixed abrasive material as the fixed abrasive material moves relative to the projected gimbal wafer carrier, wherein material removal occurs while features on the surface of the semiconductor wafer activate the micro-replicated features of the fixed abrasive material and material removal substantially stops when there are no features remaining on the surface of the semiconductor wafer.

8. The method of claim 7, wherein the projected gimbal wafer carrier has a gimbal point at approximately the surface of the semiconductor wafer.

9. The method of claim 7, wherein the projected gimbal wafer carrier has a gimbal point below the surface of the semiconductor wafer.

10. The method of claim 7, wherein the fixed abrasive material is in a belt format.

11. The method of claim 7, wherein the fixed abrasive material comprises CeO₂ particles dispersed in a polymer matrix.

12. A method for controlling activation of a fixed abrasive material by a leading edge of a semiconductor wafer during planarization of a surface of the semiconductor wafer, comprising:
controlling the orientation of a wafer carrier such that a leading edge of a semiconductor wafer held by the wafer carrier either remains substantially parallel to or moves away from a surface of an incoming fixed abrasive material.

13. The method of claim 12, wherein fixed abrasive material has micro-replicated features, and the orientation of the wafer carrier is controlled to prevent the micro-replicated features from being significantly activated by the leading edge of the semiconductor wafer.

14. The method of claim 12, wherein the wafer carrier is a projected gimbal wafer carrier.

15. The method of claim 14, wherein the projected gimbal wafer carrier has a gimbal point at approximately the surface of the semiconductor wafer.

16. The method of claim 14, wherein the projected gimbal wafer carrier has a gimbal point below the surface of the semiconductor wafer.

17. The method of claim 12, wherein the wafer carrier has a fluid membrane.

18. The method of claim 12, wherein the fixed abrasive material is in a belt format.

19. The method of claim 12, wherein the fixed abrasive material comprises CeO₂ particles dispersed in a polymer matrix.
